(19) United States
(12) Patent Application Publication
(10) Pub. No.: US 2025/0026631 A1
(43) Pub. Date: Jan. 23, 2025

(54) MEMS ELEMENT AND PIEZOELECTRIC ACOUSTIC DEVICE

(71) Applicant: Murata Manufacturing Co., Ltd., Nagaokakyo-shi (JP)

(72) Inventors: Hiroshi MATSUBARA, Nagaokakyo-shi (JP); Shinsuke IKEUCHI, Nagaokakyo-shi (JP); Ryosuke NIWA, Nagaokakyo-shi (JP); Gou SAITOU, Nagaokakyo-shi (JP)

(21) Appl. No.: 18/910,213

(22) Filed: Oct. 9, 2024

Related U.S. Application Data
(63) Continuation of application No. PCT/JP2023/015927, filed on Apr. 21, 2023.
(63) Continuation of application No. PCT/JP2022/046656, filed on Dec. 19, 2022.

(30) Foreign Application Priority Data
May 12, 2022 (JP) 2022-078862

(51) Int. Cl. B81B 7/00; B81C 1/00; H10N 30/045

(52) U.S. Cl. CPC B81B 7/0022; B81C 1/00698; H10N 30/045; B81B 2201/0257; B81B 2203/0127; B81B 2203/04; B81C 2201/0132; B81C 2201/0171

(57) ABSTRACT

A MEMS device is provided that includes a piezoelectric element including a piezoelectric membrane including a ferroelectric and configured to vibrate based on an application of a voltage. A device may include a diode portion electrically connected in parallel to the piezoelectric element and including a diode.

### CROSS REFERENCE TO RELATED APPLICATIONS

This application is a continuation of International Application No. PCT/JP2023/015927, filed Apr. 21, 2023, which claims priority to Japanese Patent Application No. 2022-078862, filed May 12, 2022, and International Application No. PCT/JP2022/046656, filed Dec. 19, 2022. This application is also a continuation of International Application No. PCT/JP2022/046656, filed Dec. 19, 2022, which claims priority to Japanese Patent Application No. 2022-078862, filed May 12, 2022. The entire contents of each application are hereby incorporated in their entirety.

### TECHNICAL FIELD

The present disclosure relates to a Micro Electronic Mechanical Systems (“MEMS”) element and a piezoelectric acoustic device and a method of manufacturing the MEMS element.

### BACKGROUND

A MEMS element containing a piezoelectric body has conventionally been known. Japanese Patent Laid-Open No. 2021-52305 (hereinafter, “JP '305”) shows a MEMS element including a membrane having a structure in which a piezoelectric membrane lies between a pair of electrodes.

Protection of a piezoelectric element on the occurrence of electro-static discharge (ESD) or the like is demanded. From this point of view, the conventional MEMS element is not necessarily sufficient.

### SUMMARY OF INVENTION

The present disclosure provides a MEMS element in which a piezoelectric element is protected against ESD or the like and a piezoelectric acoustic device including the same.

A MEMS element according to one aspect of the present technology includes a piezoelectric element including a piezoelectric membrane that contains a ferroelectric and vibrates by application of a voltage and a diode portion electrically connected in parallel to the piezoelectric element and including at least one diode. A piezoelectric acoustic device according to one aspect of the present technology includes the MEMS element.

In some aspects, the techniques described herein relate to a MEMS element including: a piezoelectric element including a piezoelectric membrane including a ferroelectric and configured to vibrate based on an application of a voltage; and a diode portion electrically connected in parallel to the piezoelectric element and including a diode.

In some aspects, the techniques described herein relate to a piezoelectric acoustic device including: a MEMS element including: a piezoelectric element including a piezoelectric membrane including a ferroelectric and configured to vibrate based on an application of a voltage; and a diode portion electrically connected in parallel to the piezoelectric element and including a diode.

In some aspects, the techniques described herein relate to a method of manufacturing a MEMS element including providing a piezoelectric element including a piezoelectric membrane including a ferroelectric and configured to vibrate based on an application of a voltage; and electrically connecting a diode portion in parallel to the piezoelectric element and including a diode.

According to the present technology, the MEMS element and the piezoelectric acoustic device in which the piezoelectric element is protected against ESD or the like can be provided.

### BRIEF DESCRIPTION OF DRAWINGS

In the descriptions that follow, like parts are marked throughout the specification and drawings with the same numerals, respectively. The drawings are not necessarily drawn to scale and certain drawings may be shown in exaggerated or generalized form in the interest of clarity and conciseness. The disclosure itself, however, as well as a mode of use, further features and advances thereof, will be understood by reference to the following detailed description of illustrative implementations of the disclosure when read in conjunction with reference to the accompanying drawings, wherein:

FIG. 1 is a cross-sectional view showing a process of manufacturing a MEMS element in accordance with aspects of the present disclosure;

FIG. 2 is a cross-sectional view showing the process of manufacturing a MEMS element in accordance with aspects of the present disclosure;

FIG. 3 is a cross-sectional view showing the process of manufacturing a MEMS element in accordance with aspects of the present disclosure;

FIG. 4 is a cross-sectional view showing the process of manufacturing a MEMS element in accordance with aspects of the present disclosure;

FIG. 5 is a cross-sectional view showing the process of manufacturing a MEMS element in accordance with aspects of the present disclosure;

FIG. 6 is a cross-sectional view showing the process of manufacturing a MEMS element in accordance with aspects of the present disclosure;

FIG. 7 is a diagram showing a modification of the process shown in FIG. 6 in accordance with aspects of the present disclosure;

FIG. 8 is a top view of the MEMS element in accordance with aspects of the present disclosure;

FIG. 9 is a cross-sectional view along IX-IX in FIG. 8 in accordance with aspects of the present disclosure;

FIG. 10 is a cross-sectional view along X-X in FIG. 8 in accordance with aspects of the present disclosure;

FIG. 11 is a circuit diagram of the MEMS element in accordance with aspects of the present disclosure;

FIG. 12 is a cross-sectional view of the MEMS element in accordance with aspects of the present disclosure;

FIG. 13 is a circuit diagram of the MEMS element in accordance with aspects of the present disclosure;

FIG. 14 is a top view of the MEMS element in accordance with aspects of the present disclosure;

FIG. 15 is a cross-sectional view along XV-XV in FIG. 14 in accordance with aspects of the present disclosure;

FIG. 16 is a circuit diagram of the MEMS element in accordance with aspects of the present disclosure;

FIG. 17 is a top view of the MEMS element in accordance with aspects of the present disclosure;

FIG. 18 is a cross-sectional view along XVIII-XVIII in FIG. 17 in accordance with aspects of the present disclosure;

FIG. 19 is a cross-sectional view along XIX-XIX in FIG. 17 in accordance with aspects of the present disclosure;

FIG. 20 is a cross-sectional view of the MEMS element in accordance with aspects of the present disclosure;

FIG. 21 is a cross-sectional view of the MEMS element in accordance with aspects of the present disclosure;

FIG. 22 is a top view of the MEMS element in accordance with aspects of the present disclosure;

FIG. 23 is a cross-sectional view along XXIII-XXIII in FIG. 22 in accordance with aspects of the present disclosure;

FIG. 24 is a top view of the MEMS element in accordance with aspects of the present disclosure;

FIG. 25 is a cross-sectional view along XXV-XXV in FIG. 24 in accordance with aspects of the present disclosure; and

FIGS. 26(A) to 26(C) are diagrams for illustrating a polarization direction of a piezoelectric thin membrane 40 in accordance with aspects of the present disclosure.

### DETAILED DESCRIPTION

Hereinbelow, aspects of the present disclosure will be described. In a following description of the drawings, the same or similar components will be represented with use of the same or similar reference characters. The drawings are exemplary, sizes or shapes of portions are schematic, and technical scope of the present disclosure should not be understood with limitation to the aspects.

Aspects of the present technology are described below. The same or corresponding elements have the same reference characters allotted and description thereof may not be repeated.

When the number, an amount, or the like is mentioned in an aspect described below, the scope of the present technology is not necessarily limited to the number, the amount, or the like unless otherwise specified. Each constituent element in the aspect below is not necessarily essential to the present technology unless otherwise specified. The present technology is not necessarily limited to a technology that achieves all of functions and effects mentioned in the present aspect.

The terms “comprise”, “include”, and “have” herein are open-ended. Specifically, when a certain feature is included, a feature other than that feature may or may not be included.

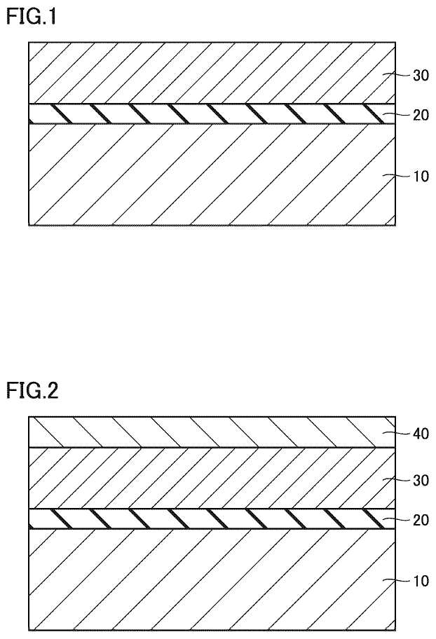

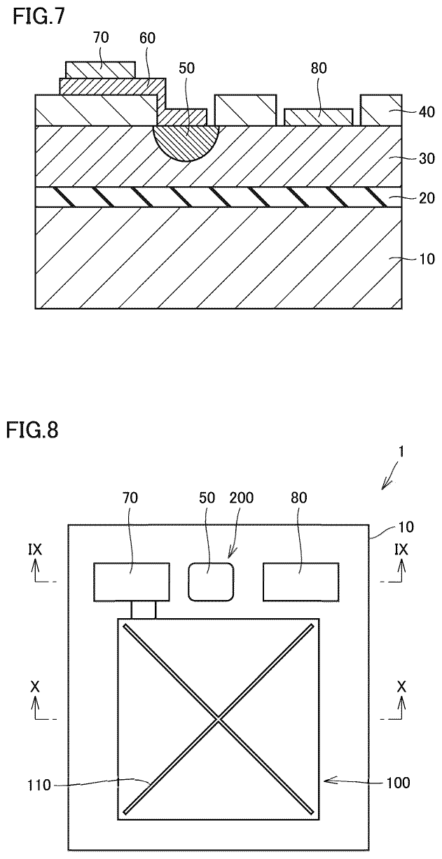

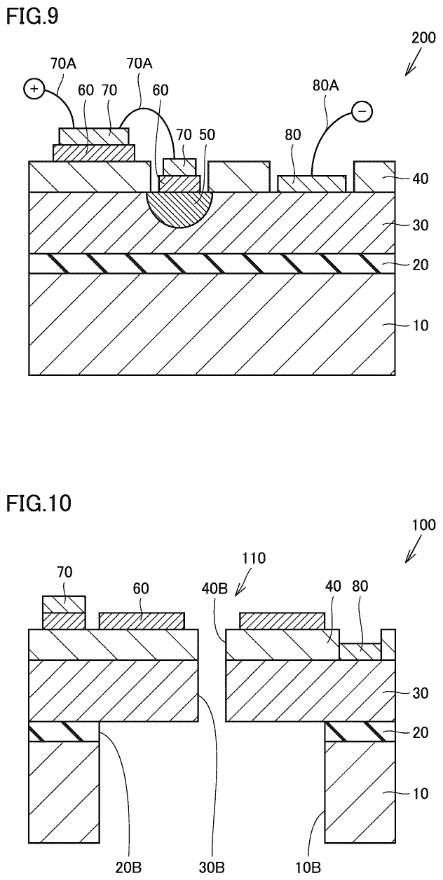

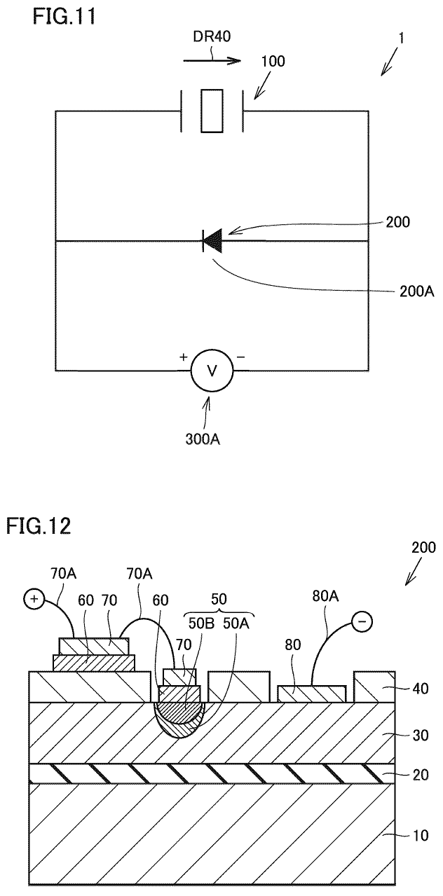

FIGS. 1 to 7 are cross-sectional views showing steps (FIG. 7 being a modification of the step shown in FIG. 6) in a process of manufacturing a MEMS element according to aspects of the present disclosure. FIG. 8 is a top view of the MEMS element according to aspects of the present disclosure, and FIGS. 9 and 10 are a cross-sectional view along IX-IX and a cross-sectional view along X-X in FIG. 8, respectively. FIG. 11 is a circuit diagram of the MEMS element according to aspects of the present disclosure.

As shown in FIG. 11, a MEMS element 1 according to aspects of the present disclosure has a structure in which a piezoelectric element 100 and a diode portion 200 are electrically connected in parallel. Diode portion 200 is composed of a single diode 200A. Piezoelectric element 100 includes a piezoelectric membrane that vibrates by application of a voltage. Piezoelectric element 100 has a membrane structure in which the piezoelectric membrane lies between a pair of electrode bodies (upper and lower electrodes). When MEMS element 1 is driven, the membrane vibrates by application of the voltage to the piezoelectric membrane. In the example in FIG. 11, MEMS element 1 is driven by a unipolar alternating-current (AC) power supply 300A.

Though MEMS element 1 is applicable, for example, to a piezoelectric micromachined ultrasonic transducer (pMUT), limitation as such is not intended. MEMS element 1 is applicable also to other piezoelectric acoustic devices such as a MEMS speaker or a MEMS microphone. Furthermore, MEMS element 1 may be applicable to a device other than the piezoelectric acoustic device.

The process of manufacturing MEMS element 1 and a cross-sectional structure of MEMS element 1 are described below with reference to FIGS. 1 to 10.

As shown in FIG. 1, an SOI wafer in which an oxide film layer 20 (BOX layer) and active layer silicon 30 (a semiconductor film) are formed on a silicon substrate 10 (semiconductor substrate) is prepared. Since active layer silicon 30 serves as a lower electrode of piezoelectric element 100, it may be required to be low in resistance. Active layer silicon 30 may have a p conductivity type or an n conductivity type. A resistivity of active layer silicon 30 is adjusted with a generally used dopant (boron, phosphorus, antimony, arsenic, or the like). A description are given below on the assumption that active layer silicon 30 has the p conductivity type.

A layered structure of silicon substrate 10, oxide film layer 20, and active layer silicon 30 described above is by way of example, and the present technology is not limited thereto. A semiconductor material other than silicon may also be applicable to the present technology.

As shown in FIG. 2, a ferroelectric piezoelectric thin membrane 40 (piezoelectric membrane) is formed on active layer silicon 30. Active layer silicon 30 abuts on piezoelectric thin membrane 40. Piezoelectric thin membrane 40 is composed of a ferroelectric such as lithium niobate (LN: LiNbO₃) and lithium tantalate (LT: LiTaO₃). A single-crystal substrate composed of such a material is bonded to active layer silicon 30 by surface activated bonding and atomic diffusion bonding. Thereafter, by grinding or the like with a grinder, the single-crystal substrate is made smaller in thickness to form piezoelectric thin membrane 40. A method of making the thickness of the single-crystal substrate smaller may also include, for example, a method of providing a damaged layer by ion implantation on a bonding surface side of a piezoelectric single-crystal substrate in advance and separating the single-crystal substrate with the use of the damaged layer after bonding, other than grinding and polishing. A method using separation and polishing may also be combined. Furthermore, ferroelectric piezoelectric thin membrane 40 may be formed also by forming a thin membrane composed of lead zirconate titanate (PZT: Pb(Zr,Ti)O₃) with a sol-gel method or sputtering.

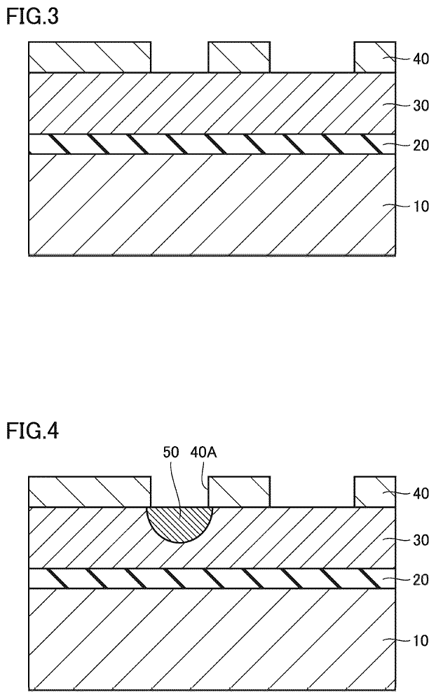

As shown in FIG. 3, piezoelectric thin membrane 40 is patterned into a desired shape. Patterning may be performed by dry etching such as reactive ion etching (RIE) or wet etching with the use of fluoronitric acid or the like.

In a region where diode portion 200 is to be formed, as shown in FIG. 4, an n-type impurity region 50 is formed in p-type active layer silicon 30. Impurity region 50 is formed by ion implantation and diffusion employed in a general semiconductor process. For example, phosphorus, arsenic, or the like is employed as the dopant. The dopant is implanted into active layer silicon 30 through an opening 40A in piezoelectric thin membrane 40.

In accordance with aspects of the present disclosure, as shown in FIG. 11, electric field in an orientation the same as a polarization direction (a direction shown with an arrow DR40) of piezoelectric thin membrane 40 is applied to piezoelectric element 100. In this case, when a voltage (V) applied to piezoelectric thin membrane 40 reaches a dielectric breakdown voltage (first voltage) of piezoelectric thin membrane 40, piezoelectric thin membrane 40 breaks. Diode 200A is formed to have as a forward direction, a direction opposite to a direction corresponding to the polarization direction of piezoelectric thin membrane 40. In order to suppress break of piezoelectric element 100, a concentration and a depth of impurity region 50 are adjusted such that a breakdown voltage (a second voltage) of diode 200A is not higher than (preferably, approximately at least 0.7 time and at most 1.0 time and more preferably approximately at least 0.8 time and at most 0.9 time) the dielectric breakdown voltage of piezoelectric thin membrane 40. A detailed description of the polarization direction of piezoelectric thin membrane 40 are described below.

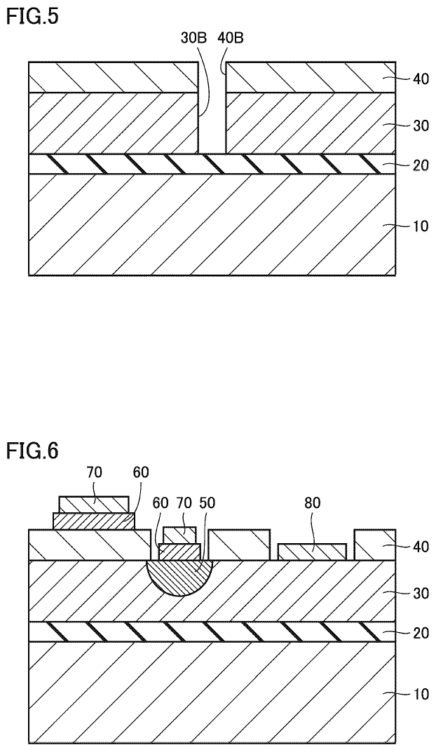

In a region where piezoelectric element 100 is to be formed, as shown in FIG. 5, openings 30B and 40B are provided in active layer silicon 30 and piezoelectric thin membrane 40, respectively. Openings 30B and 40B are provided by dry etching or the like.

As shown in FIG. 6, an upper electrode 60 is formed on a surface of piezoelectric thin membrane 40 and impurity region 50. Though upper electrode 60 may be formed, for example, of Pt, the present technology is not limited as such, and upper electrode 60 may be formed of another material such as Al.

Before upper electrode 60 is formed, an intimate contact layer (not shown) for upper electrode 60 may be formed. Though the intimate contact layer may be formed, for example, of Ti, the present technology is not limited as such, and the intimate contact layer may be formed of another material such as NiCr.

Upper electrode 60 has a thickness approximately not smaller than 0.05 μm and not larger than 0.2 μm by way of example, and the intimate contact layer has a thickness approximately not smaller than 0.005 μm and not larger than 0.05 μm by way of example.

Though upper electrode 60 and the intimate contact layer may be formed into a desired pattern, for example, by vapor deposition and lift-off, the present technology is not limited as such. For example, a film may be formed over the entire surface by sputtering and thereafter may be etched to form the pattern of upper electrode 60 and the intimate contact layer.

The pattern of upper electrode 60 is not limited to the pattern shown in FIG. 6. For example, as shown in FIG. 7, upper electrode 60 on piezoelectric thin membrane 40 and upper electrode 60 on impurity region 50 may integrally be formed.

As shown in FIGS. 6 and 7, a PAD electrode 70 is formed on upper electrode 60 and a PAD electrode 80 is formed on active layer silicon 30 exposed through opening 40A in piezoelectric thin membrane 40. Though PAD electrodes 70 and 80 may be formed, for example, of Au, the present technology is not limited as such, and PAD electrodes 70 and 80 may be formed of another material such as Al.

Before PAD electrodes 70 and 80 are formed, an intimate contact layer (not shown) for PAD electrodes 70 and 80 may be formed. Though the intimate contact layer may be formed, for example, of Ti, the present technology is not limited as such, and the intimate contact layer may be formed of another material such as NiCr.

PAD electrodes 70 and 80 have a thickness approximately not smaller than 0.1 μm and not larger than 1.0 um by way of example, and the intimate contact layer has a thickness approximately not smaller than 0.005 μm and not larger than 0.1 μm by way of example.

Though PAD electrodes 70 and 80 and the intimate contact layer may be formed into a desired pattern, for example, by vapor deposition and lift-off, the present technology is not limited as such. For example, a film may be formed over the entire surface by sputtering and thereafter may be etched to form the pattern of PAD electrodes 70 and 80 and the intimate contact layer.

As shown in FIG. 8 (top view), piezoelectric element 100 and diode portion 200 are arranged at a distance from each other on a main surface of silicon substrate 10 included in MEMS element 1. Positional relation between piezoelectric element 100 and diode portion 200 is not limited to arrangement shown in FIG. 8.

As shown in FIG. 9 (the cross-sectional view of diode portion 200), wire lines 70A and 80A opposite in polarity to each other are connected to respective PAD electrodes 70 and 80.

As shown in FIG. 10 (the cross-sectional view of piezoelectric element 100), in the region where piezoelectric element 100 is formed, openings 10A and 20A are provided in silicon substrate 10 and oxide film layer 20. Opening 10A may be provided by etching away a part of silicon substrate 10 with deep reactive ion etching (RIE). Opening 20A may be provided in oxide film layer 20 by etching away with reactive ion etching (RIE). Openings 30B and 40B provided in active layer silicon 30 and piezoelectric thin membrane 40 define slits 110 in piezoelectric element 100.

Since piezoelectric element 100 and diode portion 200 are electrically connected in parallel in MEMS element 1 according to aspects of the present disclosure, on the occurrence of ESD or the like, the current can escape toward diode portion 200 so that break of piezoelectric element 100 can be suppressed.

Since diode portion 200 is formed from impurity region 50 provided in active layer silicon 30, piezoelectric element 100 and diode portion 200 can be provided on single silicon substrate 10 (semiconductor substrate). Consequently, while MEMS element 1 is reduced in size, break of piezoelectric element 100 can be suppressed.

Diode 200A included in diode portion 200 is preferably formed to have as the forward direction, the direction opposite to the direction corresponding to the polarization direction (the direction shown with arrow DR40) of piezoelectric thin membrane 40 as in the example in FIG. 11. Since dielectric breakdown field of piezoelectric thin membrane 40 is relatively larger than coercive electric field, normally, as shown in FIG. 11, unipolar AC power supply 300A is connected in the direction corresponding to the polarization direction of piezoelectric thin membrane 40. In the example in FIG. 11, diode 200A is connected to have as the forward direction, the direction opposite to the direction corresponding to the polarization direction of piezoelectric thin membrane 40. Thus, when unipolar AC power supply 300A is connected in a wrong direction (a direction opposite to the above), diode 200A is in the forward direction and no voltage is applied to piezoelectric element 100. Consequently, break of piezoelectric element 100 by polarization reversal can be suppressed.

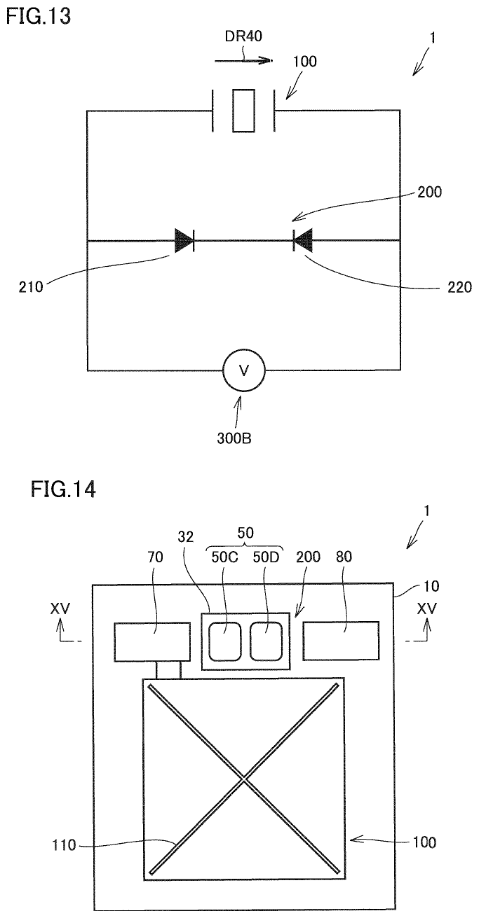

FIG. 12 is a cross-sectional view of MEMS element 1 according to aspects of the present disclosure. FIG. 13 is a circuit diagram of MEMS element 1 shown in FIG. 12.

In MEMS element 1 according to aspects of the present disclosure, diode portion 200 includes a first diode 210 having a first direction as the forward direction and a second diode 220 connected in series to first diode 210, second diode 220 having as the forward direction, a second direction opposite to the first direction, as shown in FIG. 13.

As shown in FIG. 12, an impurity region 50A (first impurity region) of an n-type (first conductivity type) is formed in the inside of p-type active layer silicon 30 and an impurity region 50B (second impurity region) of the p-type (second conductivity type) is formed in the inside of impurity region 50A. Diode portion 200 in which first diode 210 and second diode 220 oriented in directions reverse to each other are connected in series can thus be formed.

First diode 210 and second diode 220 may substantially be the same or different from each other in breakdown voltage. In the present disclosure, as shown in FIG. 13, a bipolar AC power supply 300B is employed. Therefore, electric field in the same orientation as the polarization direction (the direction shown with arrow DR40) of piezoelectric thin membrane 40 and electric field reverse in orientation are alternately applied to piezoelectric element 100.

When electric field in the orientation reverse to the polarization direction (the direction shown with arrow DR40) of piezoelectric thin membrane 40 is applied to piezoelectric element 100, upon application of coercive electric field (V/m) to piezoelectric thin membrane 40, polarization reversal occurs in piezoelectric thin membrane 40 to break piezoelectric element 100. First diode 210 is formed to have as the forward direction, the direction corresponding to the polarization direction of piezoelectric thin membrane 40. In order to suppress break of piezoelectric element 100, first diode 210 is formed at least to break down upon application of coercive electric field to piezoelectric thin membrane 40 (application of an electric field preferably approximately at least 0.7 time and at most 1.0 time as high as coercive electric field and more preferably electric field approximately at least 0.8 time and at most 0.9 time as high as coercive electric field). In other words, a concentration and a depth of impurity region 50 are adjusted such that the breakdown voltage (second voltage) of first diode 210 is equal to or lower than a voltage (first voltage) at which polarization reversal of piezoelectric thin membrane 40 occurs.

When an electric field in the orientation the same as the polarization direction (the direction shown with arrow DR40) of piezoelectric thin membrane 40 is applied to piezoelectric element 100 and when the voltage (V) applied to piezoelectric thin membrane 40 reaches the dielectric breakdown voltage (first voltage) of piezoelectric thin membrane 40, piezoelectric thin membrane 40 breaks. Second diode 220 is formed to have as the forward direction, the direction opposite to the direction corresponding to the polarization direction of piezoelectric thin membrane 40. In order to suppress a break of piezoelectric element 100, a concentration and a depth of impurity region 50 are adjusted such that the breakdown voltage (second voltage) of second diode 220 is not higher than (preferably approximately at least 0.7 time and at most 1.0 time and more preferably approximately at least 0.8 time and at most 0.9 time) the dielectric breakdown voltage of piezoelectric thin membrane 40.

Active layer silicon 30 and impurity regions 50A and 50B may each be reverse in conductivity type to the above.

In MEMS element 1 according to the present disclosure, diode portion 200 in which first diode 210 and second diode 220 oriented in directions reverse to each other are connected in series is connected in parallel to piezoelectric element 100. Therefore, even when bipolar AC power supply 300B drives MEMS element 1 and electric field exceeding coercive electric field or dielectric breakdown field is applied, a break of piezoelectric element 100 due to polarization reversal or dielectric breakdown can be suppressed.

As MEMS element 1 is driven by bipolar AC power supply 300B as above, a range of voltages that can be applied to piezoelectric thin membrane 40 becomes wider than in the example where unipolar AC power supply 300A (described above) is employed. Consequently, a transmitting sound pressure can be improved, for example, in the piezoelectric acoustic device including MEMS element 1.

MEMS element 1 according to the present disclosure can again achieve protection of piezoelectric element 100 while MEMS element 1 as a whole is reduced in size. Since the aspect is otherwise similar to the aspect described above, detailed description will not be repeated.

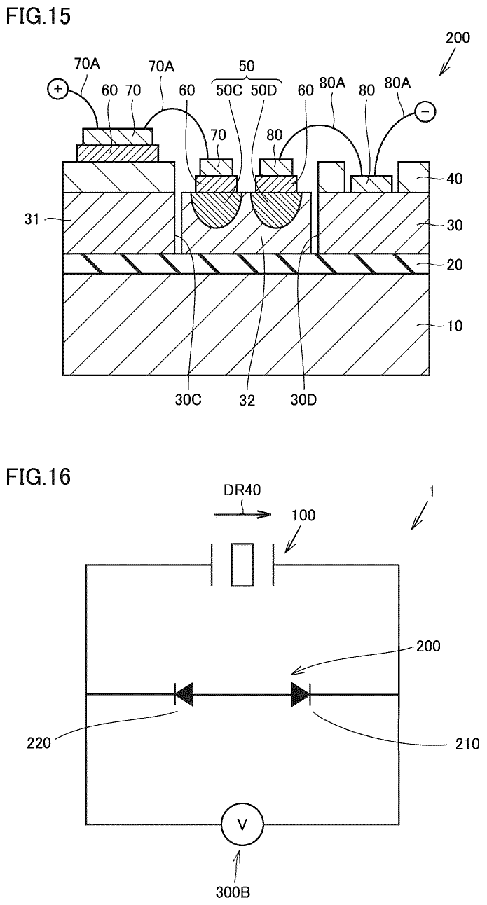

FIG. 14 is a top view of MEMS element 1 according to an aspect of the present disclosure, and FIG. 15 is a cross-sectional view along XV-XV in FIG. 14. FIG. 16 is a circuit diagram of MEMS element 1 shown in FIGS. 14 and 15.

In MEMS element 1 according to an aspect of the present disclosure, as shown in FIG. 15, diode portion 200 includes first diode 210 having the first direction as the forward direction and second diode 220 connected in series to first diode 210, second diode 220 having as the forward direction, the second direction opposite to the first direction.

As shown in FIGS. 14 and 15, active layer silicon 30 includes a first portion 31 that serves as the electrode (lower electrode) of piezoelectric thin membrane 40 and a second portion 32 separated from first portion 31.

Impurity region 50 formed in second portion 32 in p-type (second conductivity type) active layer silicon 30 includes an impurity region 50C (first impurity region) of the n-type (first conductivity type) and an impurity region 50D (second impurity region) of the n-type (first conductivity type). Impurity regions 50C and 50D are formed at a distance from each other. Impurity region 50C is connected to PAD electrode 70 and impurity region 50D is connected to PAD electrode 80. Diode portion 200 in which first diode 210 and second diode 220 oriented in directions reverse to each other are connected in series can thus be formed.

Active layer silicon 30 and impurity regions 50C and 50D may be reverse in conductivity type to the above.

MEMS element 1 according to an aspect of the present disclosure can again achieve protection of piezoelectric element 100 while MEMS element 1 as a whole is reduced in size. Since the aspect is otherwise similar to the aspects described above, a detailed description will not be repeated.

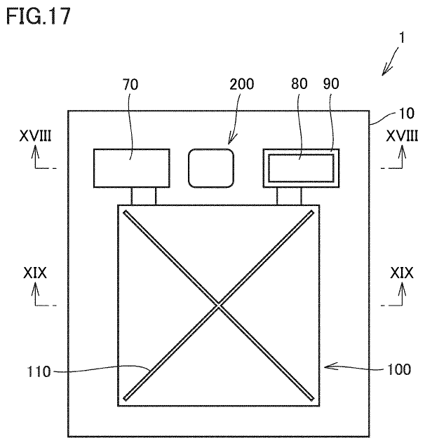

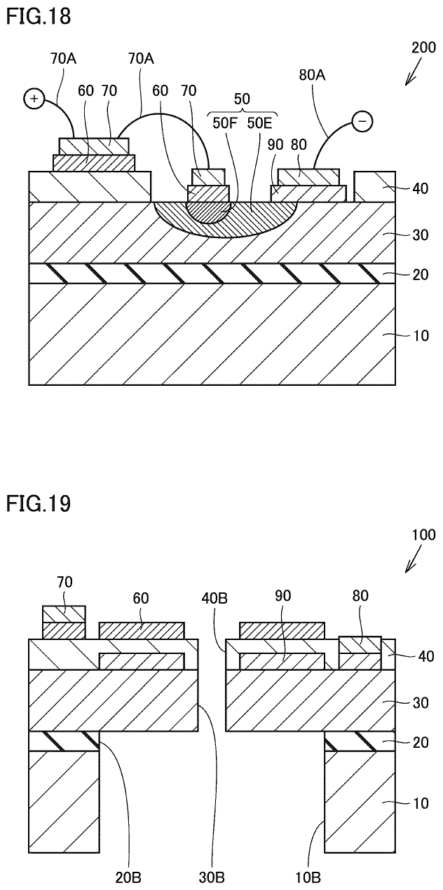

FIG. 17 is a top view of MEMS element 1 according to an aspect of the present disclosure, and FIGS. 18 and 19 are a cross-sectional view along XVIII-XVIII and a cross-sectional view along XIX-XIX in FIG. 17, respectively.

As shown in FIGS. 17 to 19, in MEMS element 1 according to an aspect of the present disclosure, a lower electrode 90 is provided below piezoelectric thin membrane 40. Lower electrode 90 may be formed of a metallic material. Lower electrode 90 is formed to be lower (less) in resistance than active layer silicon 30.

As shown in FIG. 18, an impurity region 50E (first impurity region) of the p-type (second conductivity type) is formed in the inside of p-type active layer silicon 30 and an impurity region 50F (second impurity region) of the n-type (first conductivity type) is formed in the inside of impurity region 50E. Impurity region 50F is connected to upper electrode 60 (first electrode) and PAD electrode 70, and impurity region 50E is connected to lower electrode 90 (second electrode) and PAD electrode 80. A circuit as in the aspect (FIG. 11) described above can thus be obtained.

Active layer silicon 30 and impurity regions 50E and 50F may be reverse in conductivity type to the above.

In MEMS element 1 according to an aspect of the present disclosure, lower electrode 90 lower in resistance than active layer silicon 30 is provided. Therefore, performance (lower resistance of the electrode) may be required when MEMS element 1 is used at a high frequency and when piezoelectric thin membrane 40 has a high dielectric constant can more readily be fulfilled.

Though impurity region 50 is formed in active layer silicon 30 in the illustration in FIG. 18, impurity region 50 may be formed to extend to oxide film layer 20 and silicon substrate 10.

MEMS element 1 according to an aspect can again achieve protection of piezoelectric element 100 while MEMS element 1 as a whole is reduced in size. Since the aspect is otherwise similar to each aspect described above, a detailed description will not be repeated.

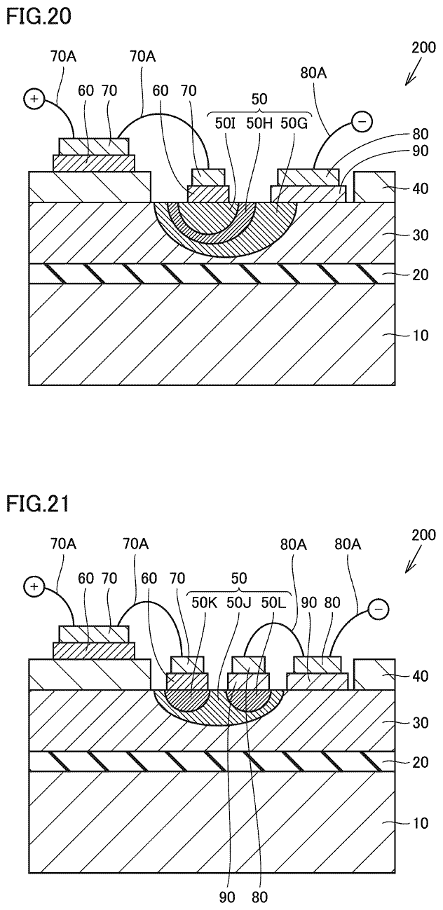

FIG. 20 is a cross-sectional view of MEMS element 1 according to an aspect of the present disclosure. As shown in FIG. 20, also in MEMS element 1 according to the present disclosure, lower electrode 90 made of metal and being low in resistance is provided as described above.

An impurity region 50G (first impurity region) of the p-type (second conductivity type) is formed in the inside of p-type active layer silicon 30, an impurity region 50H (second impurity region) of the n-type (first conductivity type) is formed in the inside of impurity region 50G, and an impurity region 50I (third impurity region) of the p-type (second conductivity type) is formed in the inside of impurity region 50H. Impurity region 50I is connected to upper electrode 60 (first electrode) and PAD electrode 70 and impurity region 50G is connected to lower electrode 90 (second electrode) and PAD electrode 80. A circuit as in the aspect (FIG. 13) described above can thus be obtained.

Active layer silicon 30 and impurity regions 50G to 50I may be reverse in conductivity type to the above. The structure of piezoelectric element 100 is the same as described above (FIG. 19).

MEMS element 1 according to the present disclosure can again achieve protection of piezoelectric element 100 while MEMS element 1 as a whole is reduced in size. Since the aspect is otherwise similar to the aspects described above, a detailed description will not be repeated.

FIG. 21 is a cross-sectional view of MEMS element 1 according to an aspect of the present disclosure. As shown in FIG. 21, also in MEMS element 1 according to the present disclosure, lower electrode 90 made of metal and being low in resistance is provided as described above.

An impurity region 50J (first impurity region) of the p-type (second conductivity type) is formed in the inside of p-type active layer silicon 30, and an impurity region 50K (second impurity region) and an impurity region 50L (third impurity region) of the n-type (first conductivity type) are formed in the inside of impurity region 50J. Impurity region 50K is connected to upper electrode 60 (first electrode) and PAD electrode 70 and impurity region 50L is connected to lower electrode 90 (second electrode) and PAD electrode 80. A circuit as (FIG. 16) described above can thus be obtained.

Active layer silicon 30 and impurity regions 50J to 50L may be reverse in conductivity type to the above. The structure of piezoelectric element 100 is the same as described above (FIG. 19).

MEMS element 1 according to the present disclosure can again achieve protection of piezoelectric element 100 while MEMS element 1 as a whole is reduced in size. Since the aspect is otherwise similar to the aspects described above, detailed description will not be repeated.

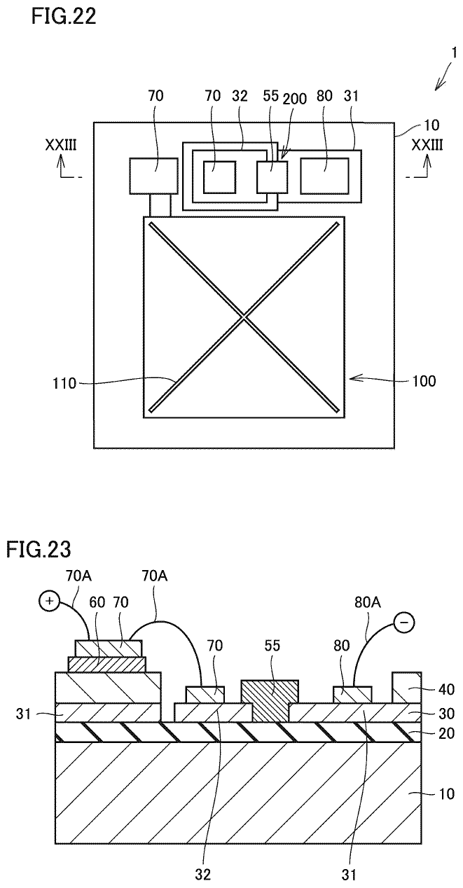

FIG. 22 is a top view of MEMS element 1 according to an aspect of the present disclosure and FIG. 23 is a cross-sectional view along XXIII-XXIII in FIG. 22.

In MEMS element 1 according to the present disclosure, diode portion 200 is implemented by a Schottky diode formed by contact of a Schottky electrode 55 made of metal with active layer silicon 30. Active layer silicon 30 includes first portion 31 that serves as the electrode (lower electrode) of piezoelectric thin membrane 40 and second portion 32 separated from first portion 31.

In the present disclosure, is an example where active layer silicon 30 of the p-type (second conductivity type) is employed, the circuit as in the aspect (FIG. 13) described above can be obtained. In an example where active layer silicon 30 of the n-type (first conductivity type) is employed, in contrast, the circuit as (FIG. 16) described above can be obtained. In any case, MEMS 1 in which diode portion 200 where first diode 210 and second diode 220 oriented in directions reverse to each other are connected in series is connected in parallel to piezoelectric element 100 is obtained.

Though metal for Schottky electrode 55 is not particularly limited, in the example where active layer silicon 30 of the n-type (first conductivity type) is employed, for example, Au, Pt, Mo, Co, W, Al, Pd, Ni, Mo, Ta, Nb, Ti, or the like can be employed as the material for Schottky electrode 55, and among these, Au and Pt can be employed as preferred materials. In the example where active layer silicon 30 of the p-type (second conductivity type) is employed, for example, Sn, In, Cs, Fr, Mg, or the like can be employed as the material for Schottky electrode 55, and among these, Sn can be employed as a preferred material.

In MEMS element 1 according to aspects of the present disclosure, piezoelectric element 100 and diode portion 200 are electrically connected in parallel as described. Therefore, on the occurrence of ESD or the like, the current can escape toward diode portion 200 so that a break of piezoelectric element 100 can be suppressed.

Since diode portion 200 is formed from Schottky electrode 55 formed on silicon substrate 10 and oxide film layer 20, piezoelectric element 100 and diode portion 200 can be provided on single silicon substrate 10 (semiconductor substrate). Consequently, a break of piezoelectric element 100 can be suppressed while MEMS element 1 is reduced in size.

Furthermore, in MEMS element 1 according to the present disclosure, diode portion 200 is formed from active layer silicon 30 and Schottky electrode 55, and hence impurity regions 50 and 50A to 50L described above do not have to be formed. Therefore, ion implantation and diffusion for formation of impurity regions 50 and 50A to 50L may not be required. Consequently, a break of piezoelectric element 100 can be suppressed in a stable manner in a simplified process.

Furthermore, diode portion 200 including the Schottky diode including Schottky electrode 55 is capable of switching operation at a higher speed than diode portion 200 including impurity regions 50 and 50A to 50L, and hence piezoelectric element 100 having the membrane structure can be driven at a higher speed.

Since the aspect is otherwise similar to the aspects described above, a detailed description will not be repeated.

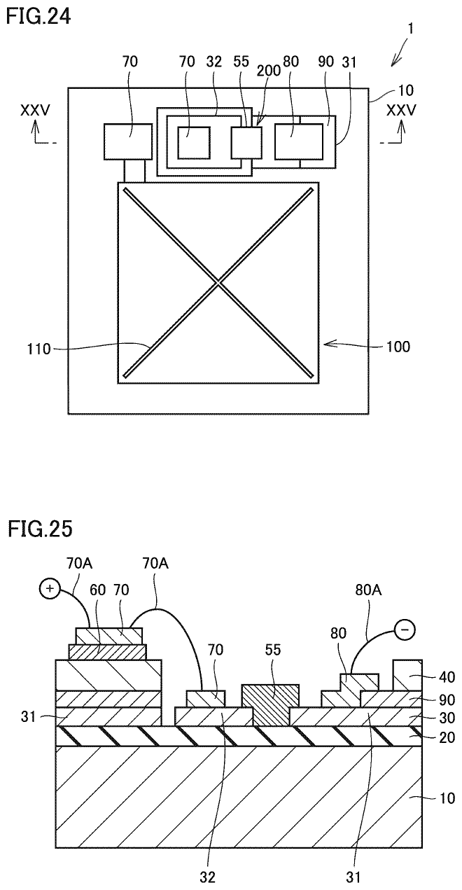

FIG. 24 is a top view of MEMS element 1 according to an aspect of the present disclosure, and FIG. 25 is a cross-sectional view along XXV-XXV in FIG. 24.

As shown in FIGS. 24 and 25, in MEMS element 1 according to the present disclosure, as described above, diode portion 200 is formed from the Schottky diode formed by contact of Schottky electrode 55 composed of metal with active layer silicon 30.

In MEMS element 1 according to the present disclosure, lower electrode 90 is further provided below piezoelectric thin membrane 40. Lower electrode 90 may be formed of a metallic material. Lower electrode 90 is formed to be lower in resistance than active layer silicon 30.

In MEMS element 1 according to the present disclosure, lower electrode 90 lower in resistance than active layer silicon 30 is provided. Therefore, performance (lower resistance of the electrode) may be required when MEMS element 1 is used at a high frequency and when piezoelectric thin membrane 40 has a high dielectric constant can more readily be fulfilled. Since the aspect is otherwise similar to the aspects described above, a detailed description will not be repeated.

MEMS element 1 according to the present disclosure can again achieve protection of piezoelectric element 100 while MEMS element 1 as a whole is reduced in size.

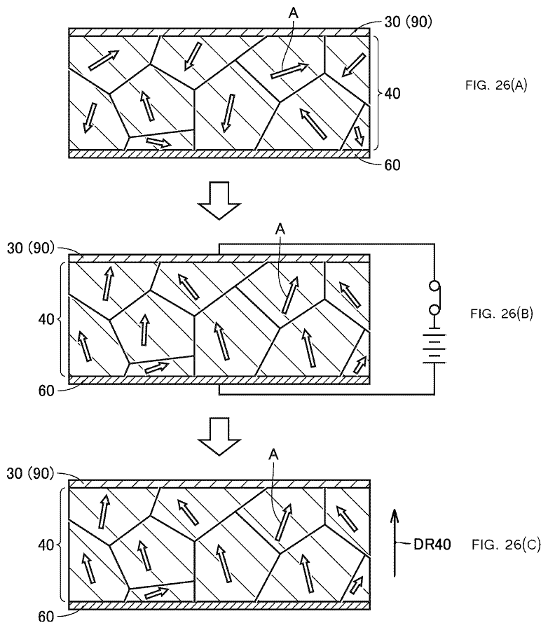

The polarization direction (the direction shown with arrow DR40 shown in FIGS. 11, 13, and 16) of piezoelectric thin membrane 40 is be described below with reference to FIGS. 26(A) and 26(C).

In an example, FIG. 26(A) shows piezoelectric thin membrane 40 composed of a ferroelectric such as PZT. In a state in FIG. 26(A), orientations (arrows A in the figure) of bias (spontaneous polarization) of charges in each crystal that forms piezoelectric thin membrane 40 are randomly formed, and there is no bias of charges in piezoelectric thin membrane 40 as a whole. As a prescribed voltage (for example, approximately 3 kV/mm) is applied to piezoelectric thin membrane 40 as shown in FIG. 26(B) from the state in FIG. 26(A), orientations of spontaneous polarization are deflected to generally be aligned (aligned upward in the example in FIGS. 26(A) to(C)). When the voltage applied to piezoelectric thin membrane 40 is removed as shown in FIG. 26(C) from a state in FIG. 26(B), orientations of spontaneous polarization do not return to the state in FIG. 26(A) but upward polarization remains in piezoelectric thin membrane 40 as a whole. In other words, the direction shown with arrow DR40 is the polarization direction of piezoelectric thin membrane 40. Alignment of the orientations of spontaneous polarization as above is referred to as polarization treatment. In an example where piezoelectric thin membrane 40 is formed from a single-crystal substrate of LN or LT, the single-crystal substrate has already been subjected to polarization treatment. In any case, the polarization direction (the direction shown with arrow DR40) of piezoelectric thin membrane 40 is an orientation the same as a direction of application of the voltage in the polarization treatment illustrated in FIG. 26(B).

In general, the description of the aspects disclosed should be considered as being illustrative in all respects and not being restrictive. The scope of the present disclosure is shown by the claims rather than by the above description and is intended to include meanings equivalent to the claims and all changes in the scope. While preferred aspects of the invention have been described above, it is to be understood that variations and modifications will be apparent to those skilled in the art without departing from the scope and spirit of the invention.

### DESCRIPTION OF REFERENCE SYMBOLS

1 MEMS element;
10 silicon substrate;
10B, 20B, 30B, 40A, 40B opening;
20 oxide film layer;
30 active layer silicon;
31 first portion;
32 second portion;
40 piezoelectric thin membrane;
50, 50A to 50L impurity region;
55 Schottky electrode;
60 upper electrode;
70, 80 PAD electrode;
70A, 80A wire line;
90 lower electrode;
100 piezoelectric element;
110 slit;
200 diode portion:
200A diode;
210 first diode:
220 second diode;
300A unipolar AC power supply; and
300B bipolar AC power supply.

What is claimed:

1. A MEMS element comprising:
a piezoelectric element including a piezoelectric membrane having a ferroelectric and configured to vibrate based on an application of a voltage; and
a diode portion electrically connected in parallel to the piezoelectric element and including a diode.

2. The MEMS element according to claim 1, wherein the piezoelectric element and the diode portion are formed on a single semiconductor substrate.

3. The MEMS element according to claim 1, wherein:
the piezoelectric element further includes an electrode formed from a semiconductor film that abuts the piezoelectric membrane, and
the diode portion further includes an impurity region in the semiconductor film.

4. The MEMS element according to claim 1, wherein a dielectric breakdown of the piezoelectric membrane is configured to occur when a first voltage is applied to the piezoelectric membrane.

5. The MEMS element according to claim 4, wherein the diode included in the diode portion has a forward direction that is a direction opposite to a direction corresponding to a polarization direction of the piezoelectric membrane, and configured to break down when a second voltage equal to or less than the first voltage is applied.

6. The MEMS element according to claim 1, wherein:
the piezoelectric element includes an electrode formed from a semiconductor film that abuts the piezoelectric membrane, and
wherein the diode portion is a Schottky diode formed by contact of metal with the semiconductor film.

7. The MEMS element according to claim 6, wherein the semiconductor film includes a first portion configured as the electrode and a second portion separated from the first portion.

8. The MEMS element according to claim 1, wherein the diode portion includes:
a first diode having a first direction corresponding to a polarization direction of the piezoelectric membrane as a forward direction, and
a second diode connected in series to the first diode, the second diode having a second direction opposite to the first direction as the forward direction, and
wherein a breakdown voltage of the first diode is equal to or less than a voltage at which polarization reversal of the piezoelectric membrane occurs, and a breakdown voltage of the second diode is equal to or less than a voltage at which dielectric breakdown of the piezoelectric membrane occurs.

9. The MEMS element according to claim 1, wherein:
the piezoelectric element includes an electrode formed from a semiconductor film that abuts on the piezoelectric membrane,
the diode portion includes:
a first diode having a first direction corresponding to a polarization direction of the piezoelectric membrane as a forward direction, and
a second diode connected in series to the first diode, the second diode having a second direction opposite to the first direction as the forward direction,
a breakdown voltage of the first diode is equal to or less than a voltage at which polarization reversal of the piezoelectric membrane occurs,
a breakdown voltage of the second diode is equal to or less than a voltage at which dielectric breakdown of the piezoelectric membrane occurs,
the first diode includes a first impurity region of a first conductivity type formed in the semiconductor film, and
the second diode includes a second impurity region of a second conductivity type formed in the first impurity region.

10. The MEMS element according to claim 1, wherein:
the piezoelectric element includes an electrode formed from a semiconductor film that abuts on the piezoelectric membrane,
the semiconductor film includes a first portion that serves as the electrode and a second portion separated from the first portion,
the diode portion includes:
a first diode having a first direction corresponding to a polarization direction of the piezoelectric membrane as a forward direction, and
a second diode connected in series to the first diode, the second diode having a second direction opposite to the first direction as the forward direction,
a breakdown voltage of the first diode is equal to or less than a voltage at which polarization reversal of the piezoelectric membrane occurs,
a breakdown voltage of the second diode is equal to or less than a voltage at which dielectric breakdown of the piezoelectric membrane occurs,
the first diode includes a first impurity region formed in the semiconductor film, and
the second diode includes a second impurity region formed in the semiconductor film, as being opposite from the first impurity region.

11. The MEMS element according to claim 1, wherein the piezoelectric element further includes:
a first electrode configured to abut the piezoelectric membrane, and
a second electrode opposite to the first electrode with respect to the piezoelectric membrane and composed of a metallic material.

12. A piezoelectric acoustic device comprising:
a MEMS element comprising:
a piezoelectric element including a piezoelectric membrane including a ferroelectric and configured to vibrate based on an application of a voltage; and
a diode portion electrically connected in parallel to the piezoelectric element and including a diode.

13. The piezoelectric acoustic device according to claim 12, wherein:
the piezoelectric element further includes an electrode formed from a semiconductor film that abuts the piezoelectric membrane, and
the diode portion further includes an impurity region formed in the semiconductor film.

14. The piezoelectric acoustic device according to claim 12, wherein the piezoelectric acoustic device includes a MEMS speaker or a MEMS microphone.

15. The piezoelectric acoustic device according to claim 12, wherein:
the piezoelectric element includes an electrode formed from a semiconductor film that abuts on the piezoelectric membrane, and
the diode portion is a Schottky diode formed by contact of metal with the semiconductor film.

16. The piezoelectric acoustic device according to claim 15, wherein the semiconductor film includes a first portion configured as the electrode and a second portion separated from the first portion.

17. The piezoelectric acoustic device according to claim 12,
wherein the diode portion includes:
a first diode having a first direction corresponding to a polarization direction of the piezoelectric membrane as a forward direction, and
a second diode connected in series to the first diode, the second diode having a second direction opposite to the first direction as the forward direction,
wherein a breakdown voltage of the first diode is equal to or less than a voltage at which polarization reversal of the piezoelectric membrane occurs, and
wherein a breakdown voltage of the second diode is equal to or less than a voltage at which dielectric breakdown of the piezoelectric membrane occurs.

18. The piezoelectric acoustic device according to claim 12, wherein:
the piezoelectric element includes an electrode formed from a semiconductor film that abuts on the piezoelectric membrane,
the diode portion includes:
a first diode having a first direction corresponding to a polarization direction of the piezoelectric membrane as a forward direction, and
a second diode connected in series to the first diode, the second diode having a second direction opposite to the first direction as the forward direction,
a breakdown voltage of the first diode is equal to or less than a voltage at which polarization reversal of the piezoelectric membrane occurs,
a breakdown voltage of the second diode is equal to or less than a voltage at which dielectric breakdown of the piezoelectric membrane occurs,
the first diode includes a first impurity region of a first conductivity type formed in the semiconductor film, and
the second diode includes a second impurity region of a second conductivity type formed in the first impurity region.

19. A method of manufacturing a MEMS element comprising:
providing a piezoelectric element including a piezoelectric membrane including a ferroelectric and configured to vibrate based on an application of a voltage; and
electrically connecting a diode portion in parallel to the piezoelectric element and including a diode.

20. The method of manufacturing according to claim 19. further comprising:
forming an electrode formed from a semiconductor film that abuts the piezoelectric membrane. and
forming an impurity region in the semiconductor film.
